(19) United States
(12) Patent Application Publication
(10) Pub. No.: US 2013/0134835 A1
(43) Pub. Date: May 30, 2013

(54) ULTRASONIC SENSOR AND MANUFACTURING METHOD THEREOF

(71) Applicants: Boum Seock KIM, Suwon (KR); Jung Min PARK, Suwon (KR); Eun Tae Park, Yongin (KR)

(72) Inventors: Boum Seock KIM, Suwon (KR); Jung Min PARK, Suwon (KR); Eun Tae Park, Yongin (KR)

(73) Assignee: SAMSUNG ELECTRO-MECHANICS CO., LTD.

(21) Appl. No.: 13/361,539

(22) Filed: Jan. 30, 2012

(30) Foreign Application Priority Data
Nov. 28, 2011 (KR) 10-2011-0124987

(51) Int. Cl. H01L 41/04; C04B 37/00; H01L 41/047

(52) U.S. Cl. 310/346; 264/614; 264/434

(57) ABSTRACT

There is provided an ultrasonic sensor including: a piezoelectric vibration element; and a capacitor integrally formed with the piezoelectric vibration element.

### CROSS-REFERENCE TO RELATED APPLICATIONS

This application claims the priority of Korean Patent Application No. 10-2011-0124987 filed on Nov. 28, 2011, in the Korean Intellectual Property Office, the disclosure of which is incorporated herein by reference.

### BACKGROUND OF THE INVENTION

1. Field of the Invention

The present invention relates to an ultrasonic sensor and a manufacturing method thereof, and more particularly, to an ultrasonic sensor integrated with a capacitor for temperature compensation and a manufacturing method thereof.

2. Description of the Related Art

An ultrasonic sensor can transmit ultrasonic waves to peripheral objects and can sense a distance thereto by using ultrasonic waves reflected therefrom.

An ultrasonic sensor, mounted in vehicles such as a car, or the like, has been used as a unit that senses a location of nearby objects and peripheral objects and helps to prevent collisions therewith.

Generally, an ultrasonic sensor includes a piezoelectric element as a unit to generate ultrasonic waves. However, the capacitance of the piezoelectric element may be widely varied according to temperature and thus, a sensing deviation may be very large according to temperature.

For this reason, the ultrasonic sensor includes a temperature compensation element to compensate for the temperature variations affecting the piezoelectric element.

However, in order to mount the temperature compensation element in the ultrasonic sensor, a separate circuit board and a connection member are further required, thereby increasing the manufacturing costs of the ultrasonic sensor and complicating the manufacturing process thereof.

### SUMMARY OF THE INVENTION

An aspect of the present invention provides an ultrasonic sensor capable of being simply manufactured while having reduced ultrasonic sensor performance deviation according to temperature, and a manufacturing method thereof.

According to an aspect of the present invention, there is provided an ultrasonic sensor including: a piezoelectric vibration element; and a capacitor integrally formed with the piezoelectric vibration element.

The piezoelectric vibration element may include a polarized ceramic member.

The capacitor may include a non-polarized ceramic member.

The ultrasonic sensor may further include: an electrode pattern connecting the piezoelectric vibration element to the capacitor.

The piezoelectric vibration element and the capacitor may be formed as a ceramic multilayered structure.

The ceramic multilayered structure may include: a first ceramic member having a first electrode pattern formed on a top surface thereof and configuring the piezoelectric vibration element; and a second ceramic member formed on the first ceramic member, having a second electrode pattern, and configuring the capacitor.

The ultrasonic sensor may further include: a third electrode pattern formed on a first end surface of the first ceramic member and a first end surface of the second ceramic member and connected with the first electrode pattern; and a fourth electrode pattern formed on a second end surface of the first ceramic member and a second end surface of the second ceramic member and connected with the second electrode pattern.

The ultrasonic sensor may further include a case formed of a conductive material, wherein the case is electrically connected with the fourth electrode pattern.

The ultrasonic sensor may further include a first connection terminal electrically connected with the case; and a second connection terminal electrically connected with the third electrode pattern.

The ultrasonic sensor may further include: a third electrode pattern formed on the first end surface of the first ceramic member and the first end surface of the second ceramic member and connected with the first electrode pattern; and a fourth electrode pattern formed on the second end surface of the first ceramic member and the second end surface of the second ceramic member and connected with the second electrode pattern.

The ultrasonic sensor may further include: a first connection terminal electrically connected with the fourth electrode pattern; and a second connection terminal electrically connected with the third electrode pattern.

The ceramic multilayered structure may include: at least two 1a ceramic members having a 1a electrode pattern extending from the top surface thereof to the first end surface thereof; a 1b ceramic member having a 1b electrode pattern extending from the top surface thereof to the second end surface thereof, and disposed between the 1a ceramic members; and a second ceramic member formed on the top surface of the 1a ceramic member and having the second electrode pattern formed on the top surface thereof, wherein the 1a and 1b ceramic members may configure the piezoelectric vibration element and the second ceramic member may configure the capacitor.

According to another aspect of the present invention, there is provided a method of manufacturing an ultrasonic sensor, including: preparing a first polarized ceramic member; forming a second non-polarized ceramic member on a top surface of the first polarized ceramic member; and compressing and sintering the first polarized ceramic member and the second non-polarized ceramic member.

The method of manufacturing an ultrasonic sensor may further include forming an electrode pattern on the first polarized ceramic member and on the second non-polarized ceramic member.

The preparing may include applying high voltage to the first polarized ceramic member.

According to another aspect of the present invention, there is provided a method of manufacturing an ultrasonic sensor, including: preparing a first ceramic member having electrode patterns formed on a top surface and a bottom surface thereof; preparing a second ceramic member having the electrode pattern formed on the top surface thereof; multilayering the first ceramic member and the second ceramic member and compressing and sintering the multilayered first ceramic member and second ceramic member; and polarizing the first ceramic member by applying high voltage to the electrode pattern of the first ceramic member.

The method of manufacturing am ultrasonic sensor may further include connecting the electrode pattern of the first ceramic member and the electrode pattern of the second ceramic member to each other.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of an ultrasonic sensor according to a first embodiment of the present invention;

FIG. 2 is a cross-sectional view of an ultrasonic sensor according to a second embodiment of the present invention;

FIG. 3 is a cross-sectional view of an ultrasonic sensor according to a third embodiment of the present invention;

FIG. 4 is a cross-sectional view of an ultrasonic sensor according to a fourth embodiment of the present invention;

FIG. 5 is a diagram showing a method of manufacturing the ultrasonic sensor according to the first embodiment of the present invention; and

FIG. 6 is a diagram showing a method of manufacturing the ultrasonic sensor according to the second embodiment of the present invention.

### DETAILED DESCRIPTION OF THE EMBODIMENTS

Generally, an ultrasonic sensor may further include a temperature compensation element (for example, capacitor for temperature compensation) together with a piezoelectric vibration element for ultrasonic oscillator in order to significantly reduce measurement deviations for surrounding temperature.

However, the ultrasonic sensor according to the related art has a structure in which the piezoelectric vibration element and the temperature compensation device are separated from each other and therefore, a structure of the ultrasonic sensor is complicated and it is difficult to perform a manufacturing method thereof.

For example, the ultrasonic sensor according to the related art may have inconvenience in further including a separate circuit board and individually connecting between the temperature compensation device and the circuit board and between the circuit board and the piezoelectric vibration device.

The embodiments of the present invention are to improve the above defects and may provide an ultrasonic sensor in which a piezoelectric vibration element and a temperature compensation element are integrally formed with each other by using a ceramic member characteristic.

In particular, according to the embodiments of the present invention, the piezoelectric vibration element and the temperature compensation element may be integrated in a single part type, the electrical connection between these devices may be facilitated, and these devices may be miniaturized.

Therefore, according to embodiments of the present invention, miniaturization of the ultrasonic sensor and simplification of a process of manufacturing the ultrasonic sensor may be promoted.

Hereinafter, embodiments of the present invention will be described in detail based on the accompanying drawings.

Hereinafter, in describing the embodiments of the present invention, terms indicating components of the present invention are named in consideration of a function of each component and are not construed to limit technical components of the present invention.

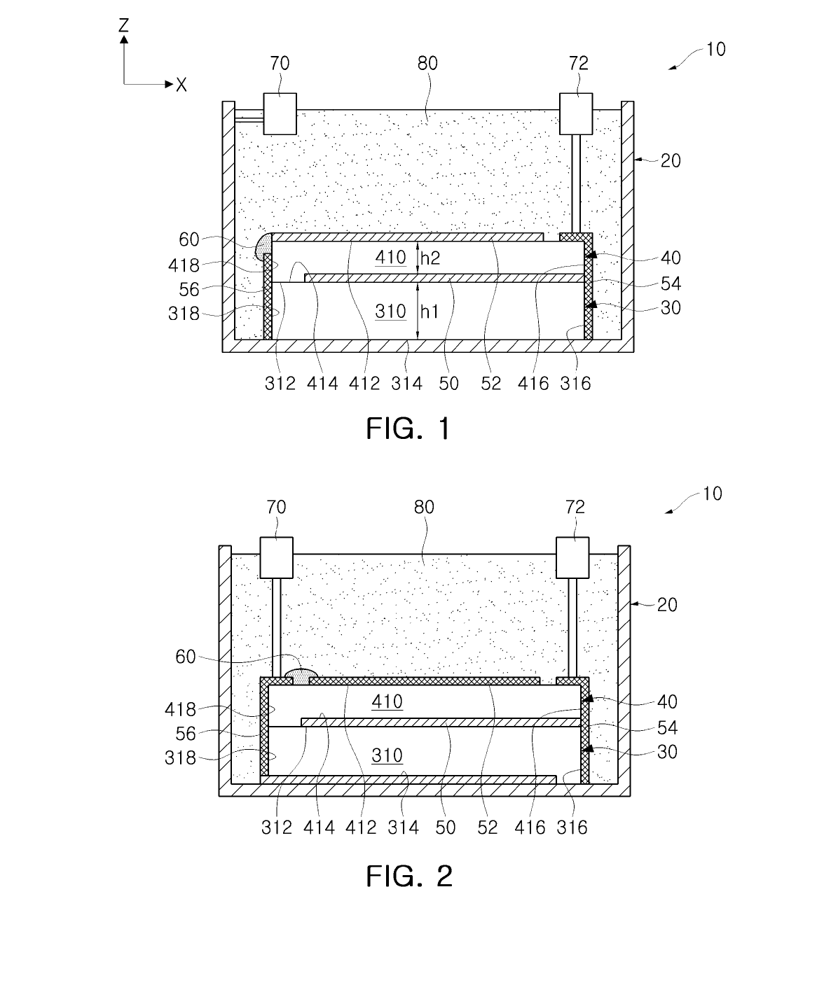

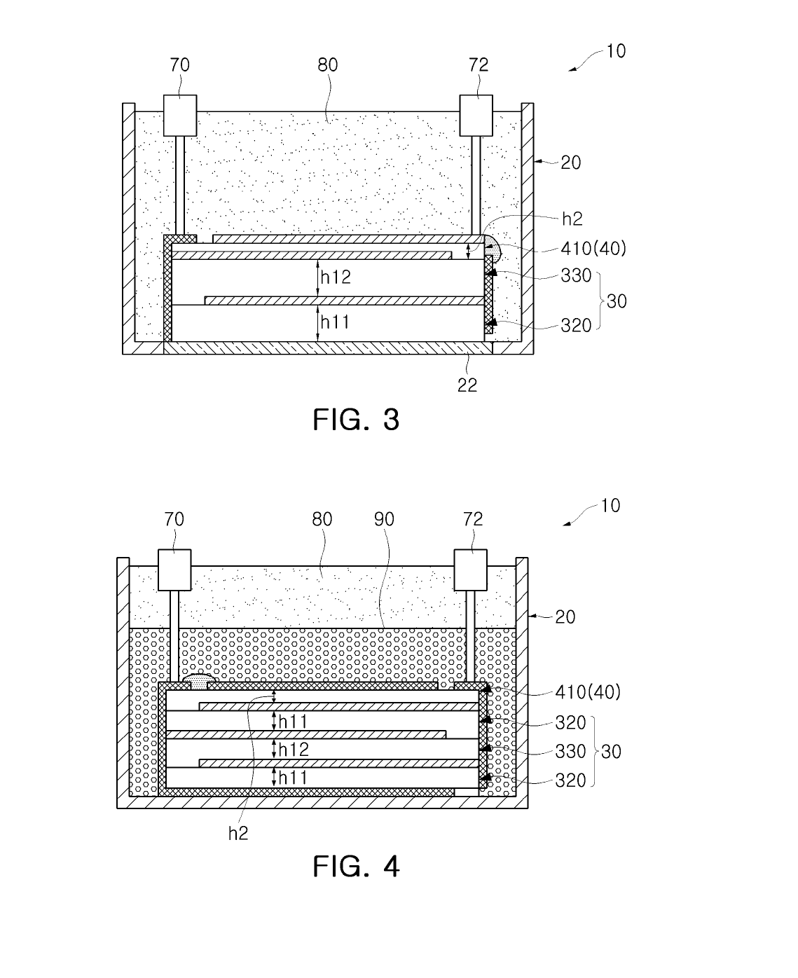

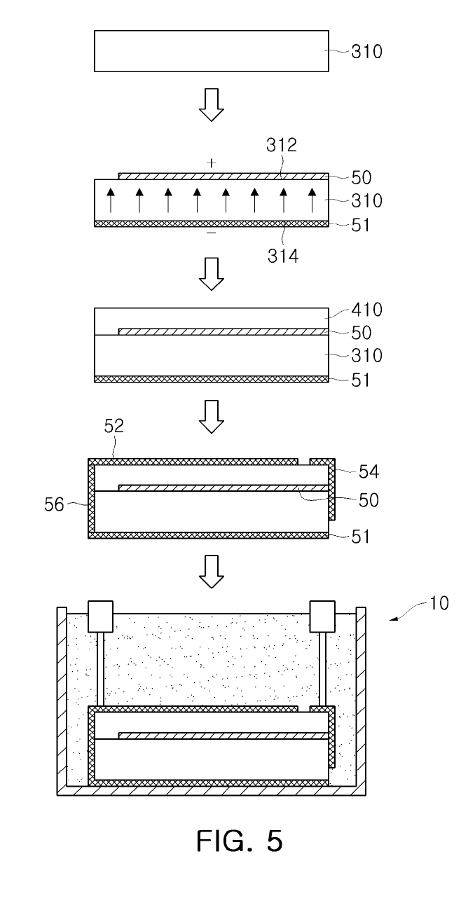

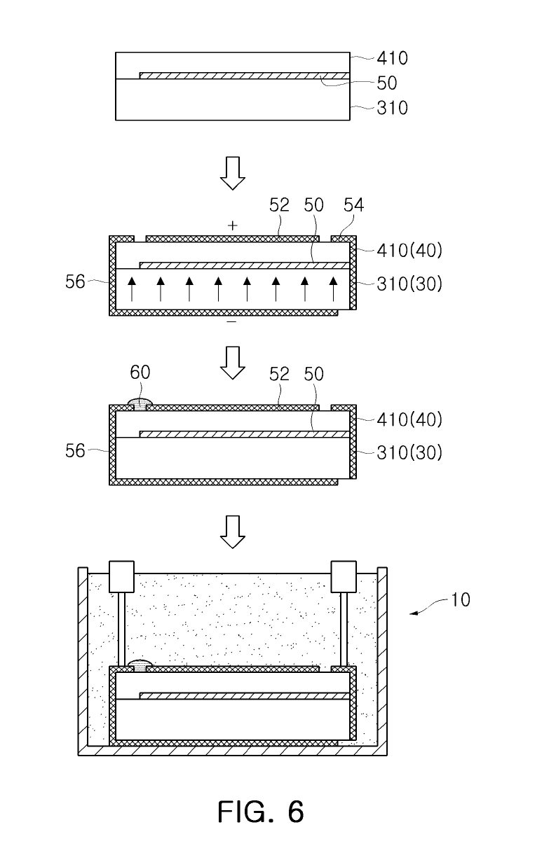

FIG. 1 is a cross-sectional view of an ultrasonic sensor according to a first embodiment of the present invention, FIG. 2 is a cross-sectional view of an ultrasonic sensor according to a second embodiment of the present invention, FIG. 3 is a cross-sectional view of an ultrasonic sensor according to a third embodiment of the present invention, FIG. 4 is a cross-sectional view of an ultrasonic sensor according to a fourth embodiment of the present invention, FIG. 5 is a diagram showing a method of manufacturing the ultrasonic sensor according to the first embodiment of the present invention, and FIG. 6 is a diagram showing a method of manufacturing the ultrasonic sensor according to the second embodiment of the present invention.

An ultrasonic sensor according to a first embodiment of the present invention will be described with reference to FIG. 1.

An ultrasonic sensor 10 according to a first embodiment of the present invention may include a case 20, a piezoelectric vibration element 30, and a temperature compensation capacitor 40 (hereinafter, simply referred to as a capacitor) and may further include connection terminals 70 and 72 and an encapsulating member 80.

The case 20 may be formed to have a shape having a receiving space (for example, a cylindrical shape) therein and may be formed of a metallic material. However, the case 20 may be a prism shape having a polygonal cross section (for example, a rectangular shape) and may be formed of easily formed materials besides metallic materials. Further, the case 20 may also be omitted in a case in which the ultrasonic sensor 10 is integrally formed with parts (for example, tail end lamp, a bumper, or the like).

Meanwhile, in the embodiment of the present invention, the case 20 may be formed of metallic materials having conductivity and may have a metal pattern therein so as to facilitate an electrical connection between the first connection terminal 70 and the piezoelectric vibration element 30. In the latter case, the metal patterns may be formed in the case 20 through a post-process (for example, an adhesive process) or may be integrally formed in a molding process of the case 20 (for example, insert injection molding).

The piezoelectric vibration element 30 may be formed in the case 20. In other words, the piezoelectric vibration element 30 may be formed at a portion (a bottom of the case 20 in the embodiment of the present invention) that can easily transfer ultrasonic waves from the case 20 to the outside.

The piezoelectric vibration element 30 may transmit the ultrasonic waves to the outside in response to electrical signals therein. For example, the piezoelectric vibration element 30 may transmit a frequency of 40 kHz or more. Along therewith, the piezoelectric vibration element 30 may receive ultrasonic waves reflected by colliding with adjacent objects, convert the received ultrasonic waves into the electrical signals, and transmit the electrical signals to an internal circuit. For reference, the piezoelectric vibration element 30 may be connected with the internal circuit via a first connection terminal 70 and a second connection terminal 72.

The capacitor 40 may be formed in the piezoelectric vibration element 30. In other words, the capacitor 40 may be electrically connected with the piezoelectric vibration element 30. The capacitor 40 formed as described above may compensate for the change in capacitance according to the external temperature. In this case, the capacitor 40 may include capacitance of 1500 pF or more so as to sufficiently compensate for the change in capacitance according to the temperature.

Meanwhile, in the embodiment, the piezoelectric vibration element 30 and the capacitor 40 may be integrally formed. For example, the piezoelectric vibration element 30 and the capacitor 40 may be formed in a multilayered structure of ceramic members 310 and 410.

That is, the piezoelectric vibration element 30 may include the first ceramic member 310 and the capacitor 40 may include the second ceramic member 410 formed on the first ceramic member 310.

The first ceramic member 310 may be formed of polarized ceramic so as to include a piezoelectric vibration element characteristic. For example, the first ceramic member 310 may be ceramic subjected to a polarization process by high voltage. Unlike this, the second ceramic member 410 may be non-polarized ceramic so as to have capacitor characteristics.

In this case, a height h1 of the first ceramic member 310 may be higher than a height h2 of the second ceramic member 410. In other words, the first ceramic member 310 may have a relatively high height so as to increase piezoelectric efficiency according to the electrical signals and the second ceramic member 410 may have a relatively low height so as to increase the capacitance of the capacitor 40.

The first ceramic member 310 and the second ceramic member 410 may be integrated through a compressing and sintering process. That is, the first ceramic member 310 and the second ceramic member 410 may be in a non-sintered state at the time of multilayer and may be integrated through the compressing and sintering process after being multilayered. Here, the compressing and sintering process may be performed after the internal electrode (electrode pattern of reference numeral 50) is formed between the first ceramic member 310 and the second ceramic member 410.

Electrode patterns 50, 52, 54, and 56 may be formed on the ceramic members 310 and 410. The electrode patterns represented by reference numerals 50 and 52 among the plurality of electrode patterns may form electrodes having first polarity and second polarity in the ceramic members 310 and 410.

For example, the first electrode pattern 50 may be formed on a top surface 312 of the first ceramic member 310 and a bottom surface 414 of the second ceramic member 410 to provide the first polarity to the first ceramic member 310 and the second ceramic member 410. In other words, the first electrode pattern 50 may lengthily extend from the top surface 312 of the first ceramic member 310 to an end surface 316 thereof and thus, may be connected with the third electrode pattern 54 but may not be connected with a fourth electrode pattern 56 of a second end surface 318 thereof.

The second electrode pattern 52 may be formed on the top surface 412 of the second ceramic member 410 to provide the second polarity to the second ceramic member 410. In this case, the second electrode pattern 52 may lengthily extend from the top surface 412 of the second ceramic member 410 to an end surface 418 thereof and thus, may be connected with the fourth electrode pattern 56 but may not be connected with a third electrode pattern 54 of the first end surface 416 thereof.

The third electrode pattern 54 may be formed on the first end surface 316 of the first ceramic member 310 and the first end surface 416 of the second ceramic member 410 and may be used as an external electrode that connects the first electrode pattern 50 with the second connection terminal 72. In other words, the third electrode pattern 54 may lengthily extend from an upper end of the first end surface 416 of the second ceramic member 410 to the first end surface 316 of the first ceramic member 310. However, in the embodiment of the present invention, the third electrode pattern 54 may be formed on the first end surface 316 of the first ceramic member 310 within a range in which the third electrode pattern does not contact the case 10.

The fourth electrode pattern 56 may be formed on the second end surface 318 of the first ceramic member 310 and the second end surface 418 of the second ceramic member 410 and may be connected with the second electrode pattern 52 via a conductive member 60 (for example, conductive adhesive). In other words, the fourth electrode pattern 56 may lengthily extend from an upper end of the second end surface 418 of the second ceramic member 410 to a lower end of the second end surface 318 of the first ceramic member 310 and thus, may be connected with the case 20.

In the above-mentioned configuration, the first electrode pattern 50 formed within the ceramic members 310 and 410 may be formed of conductive paste including Ni and the remaining electrode patterns 52, 54, and 56 formed on outer surfaces of the ceramic members 310 and 410 may be formed of conductive paste including Cu or Ag.

However, components of the electrode patterns 50, 52, 54, and 56 are not limited to the aforementioned components but may be formed of one of precious metals of Ag or Pt, one of Ni and Cu, or a mixture including at least two materials thereof.

In the multilayered structure of the ceramic members 310 and 410 configured as described above, the first ceramic member 310 and the first electrode pattern 50 may form the piezoelectric vibration element 30 and the second ceramic member 410, the first electrode pattern 50, and the second electrode pattern 52 may form the capacitor 40.

In other words, the first electrode pattern 50 and the case 20 may be used as an electrode of the first ceramic member 310 and the first electrode pattern 50 and the second electrode pattern 52 may be used as an electrode of the second ceramic member 410.

The connection terminals 70 and 72 may be connected with an internal circuit. Further, the connection terminals 70 and 72 may provide polarity to the ceramic members 310 and 410 while being electrically connected with the electrode patterns 50, 52, 54, and 56.

For example, the first connection terminal 70 may provide the second polarity to the bottom surface 314 of the first ceramic member 310 through the case 20 and may provide the second polarity to the top surface 412 of the second ceramic member 410 through the second electrode pattern 52. In this case, the second electrode pattern 52 may be connected with the first connection terminal 70 via the fourth electrode pattern 56 and the case 20.

Further, the second connection terminal 72 may provide the first polarity to each of the top surface 312 of the first ceramic member 310 and the bottom surface 414 of the second ceramic member 410 through the first electrode pattern 50. In this case, the first electrode pattern 50 may be connected with the second connection terminal 72 via the third electrode pattern 54.

The encapsulating member 80 may be provided to fill the case 20. The encapsulating member 80, formed of resin as an insulating material, may block moisture or other foreign materials from being infiltrated into the case 20.

In the ultrasonic sensor 10 configured as described above, as described above, the piezoelectric vibration element 30 and the capacitor 40 may be integrally configured by the multilayer structure of the ceramic members 310 and 410, such that the ultrasonic sensor 10 may be easily manufactured and the electrical connection structure between the piezoelectric vibration element 30 and the capacitor 40 may be simplified.

Next, other embodiments of the present invention will be described with reference to FIGS. 2 to 4.

The ultrasonic sensor 10 according to a second embodiment of the present invention may be differentiated from the first embodiment of the present invention in that the fourth electrode pattern 56 extends from the second end surface 318 of the first ceramic member 310 to the bottom surface 314 thereof.

That is, in the embodiment of the present invention, the fourth electrode pattern 56 may be formed on the bottom surface 314 of the first ceramic member 310 to provide the second polarity to the first ceramic member 310. Herein, the fourth electrode pattern 56 may be lengthily formed from the second end surface 318 of the first ceramic member 310 to the first end surface 316 thereof while being formed from the upper end of the second end surface 418 of the second ceramic member 410 to the lower end of the second end surface 318 of the first ceramic member 310. However, the extending length of the fourth electrode pattern 56 may be limited in +X-axis direction so as not to be connected with the third electrode pattern 54.

According to the embodiment of the present invention configured as described above, the case 20 does not need to be formed of the conductive material since the first electrode pattern 50 and the fourth electrode pattern 56 provide polarity to the first ceramic member 310. Therefore, the ultrasonic sensor 10 according to the embodiment of the present invention, the case 20 may be formed of a relatively light plastic material.

The ultrasonic sensor 10 according to the third embodiment of the present invention may be differentiated from the above-mentioned embodiments of the present invention in that a portion of the case 20 is formed of a conductive material. That is, according to the third embodiment of the present invention, a bottom member 22 of the case 20 may be formed of a conductive material.

Further, the ultrasonic sensor 10 according to the third embodiment of the present invention may be differentiated from the above-mentioned embodiments of the present invention in that the first ceramic members 320 and 330 may be formed of two layers.

That is, the first ceramic member may be configured by a multilayered structure including a 1a ceramic member 320 and a 1b ceramic member 330. In this case, each of a height h11 of the 1a ceramic member 320 and a height h12 of the 1b ceramic member 330 may be equal to or larger than the height h2 of the second ceramic member 410. In the former case, since the ceramic members 320, 330, and 410 having the same size may be used, the simultaneous manufacturing of the piezoelectric vibration element 30 and the capacitor 40 may be facilitated.

In the ultrasonic sensor 10 configured as described above, the piezoelectric vibration element 30 may be configured to include two sheets of ceramic members 320 and 330, thereby improving the transmission and receiving sensitivity of the ultrasonic wave.

Further, since the piezoelectric vibration element 30 and the capacitor 40 may be configured by the ceramic members 320, 330, and 410 having the same size, thereby facilitating the manufacturing of the ultrasonic sensor 10.

The ultrasonic sensor 10 according to a fourth embodiment of the present invention may be differentiated from the above-mentioned embodiments of the present invention in that the piezoelectric vibration element 30 includes three sheets of ceramic members 320, 330, and 320 and further includes a sound absorbing material 90.

In other words, according to the fourth embodiment of the present invention, the piezoelectric vibration element 30 may be configured by the multilayered structure having the 1a ceramic member 320 and the 1b ceramic member 330. In this case, the 1a ceramic member 320 may have the same electrode pattern and may be disposed on an odd numbered layer in the multilayered structure. Unlike this, the 1b ceramic member 330 may have electrode patterns different from those of the 1a ceramic member 320 and may be disposed on an even numbered layer in the multilayered structure.

The piezoelectric vibration element 30 configured as described above may include the plurality of piezoelectric materials (that is, ceramic members), thereby improving the transmission and receiving sensitivity of ultrasonic waves. Therefore, the ultrasonic sensor according to the embodiment of the present invention may be mounted in an apparatus which needs to precisely sense objects.

For reference, the respective heights h11 and h12 of the 1a and 1b ceramic members 320 and 330 may be equal to or different from the height h2 of the second ceramic member 410.

Meanwhile, the fourth embodiment of the present invention may further include the sound absorbing material 90. The sound absorbing material 90 may be formed in a portion in which the ceramic members 320, 330, and 410 are disposed and may remove noises generated from the ceramic members 320, 330, and 410.

Next, a method of manufacturing an ultrasonic sensor according to an embodiment of the present invention will be described with reference to FIGS. 5 and 6.

The ultrasonic sensor according to the embodiment of the present invention, in particular, the piezoelectric vibration element 30 and the capacitor 40 may be manufactured by two methods.

One method is a method (see FIG. 5) for manufacturing a multilayered structure including the piezoelectric vibration element 30 and the capacitor 40 by multilayering the ceramic members in which whether the polarization is formed has been already determined, and the other method is a method (see FIG. 6) for multilayering the ceramic members and then forming necessary polarization in the ceramic member.

The method of manufacturing an ultrasonic sensor according to a first embodiment of the present invention will be described with reference to FIG. 5.

The method of manufacturing an ultrasonic sensor according to the embodiment of the present invention may include polarizing a first ceramic member, forming a second ceramic member, forming external electrode patterns, and assembling.

(Polarizing First Ceramic Member)

The polarizing may be performed to form polarization in the first ceramic member 310.

First, the first ceramic member 310 is prepared. In this case, the first ceramic member 310 is a member configuring the piezoelectric vibration element 30 and thus, may have a predetermined thickness.

Next, the electrode patterns 50 and 51 may be formed on the top surface 312 and the bottom surface 314 of the first ceramic member 310. Here, the formation of the electrode patterns 50 and 51 may be performed by screen printing a conductive paste. As the conductive paste, a mixture including Ni, but may include a mixture including Cu or Ag.

Thereafter, a high voltage current may be applied to the first ceramic member 310 via the electrode patterns 50 and 51. Then, polarization may be formed in the first ceramic member 310 according to polarity of the electrode patterns 50 and 51, such that the first ceramic member 310 may have piezoelectric material characteristics.

(Forming Second Ceramic Member)

The forming may be performed to form a second non-polarized ceramic member 410 in the first ceramic member 310.

When the polarization of the first ceramic member 310 is completed, the second ceramic member 410 may be formed on the top surface 312 of the first ceramic member 310. Here, the second ceramic member 410 may be a ceramic mixture in which polarization is not formed.

Next, the first ceramic member 310 and the second ceramic member 410 may be compressed and sintered. Then, the first ceramic member 310 and the second ceramic member 410 may be integrally formed.

(Forming External Electrode Pattern)

When the first ceramic member 310 and the second ceramic member 410 are integrally formed through the sintering process, the electrode patterns 52, 54, and 56 may be further formed in the multilayered structure including the first ceramic member 310 and the second ceramic member 410.

Here, the electrode pattern 54 may be connected with the electrode pattern represented by reference numeral 50 and the electrode pattern 56 may be connected with reference numerals 51 and 52.

The electrode patterns 50, 51, 52, 54, and 56 formed as described above may provide polarity to the first ceramic member 310 and the second ceramic member 410. For example, the electrode patterns represented by reference numerals 50 and 51 may provide the first polarity and the second polarity to the first ceramic member 310, and the electrode patterns represented by reference numerals 50 and 52 may provide the first polarity and the second polarity to the second ceramic member 410.

However, the first ceramic member 310 is polarized and thus, may be connected with the internal circuit, such that the first ceramic member 310 may serve as the piezoelectric vibration element 30. Unlike this, the second ceramic member 410 is not polarized and may be connected with the internal circuit, such that the second ceramic member 410 may serve as the capacitor 40.

(Assembling)

The piezoelectric vibration device 30 and the capacitor 40 that have been completed through the above processes may be integrally mounted in the case 20 and may be connected with the connection terminals 70 and 72, thereby completing the ultrasonic sensor 10.

Herein, the piezoelectric vibration device 30 and the capacitor 40 may be commonly connected with the connection terminals 70 and 72 by the electrode patterns 50, 51, 52, 54, and 56, such that the electrical connection may be relatively easily undertaken.

Next, a method of manufacturing an ultrasonic sensor according to a second embodiment of the present invention will be described with reference to FIG. 6.

The method of manufacturing an ultrasonic sensor according to the embodiment of the present invention may be differentiated from the aforementioned embodiments of the present invention in that the polarization of the first ceramic member 310 is performed after the formation of the electrode patterns 50, 52, 54, and 56.

The method of manufacturing an ultrasonic sensor according to the embodiment of the present invention may include multilayering the ceramic members, forming the electrode pattern, polarizing, connecting the electrode patterns, and assembling. For reference, the assembling is the same or similar to the method of manufacturing according to the first embodiment and therefore, the detailed description thereof will be omitted.

(Multilayering Ceramic Members)

The multilayering may be performed by multilayering the first ceramic member 310 and the second ceramic member 410. Describing in detail, the multilayering may be performed by vertically (based on FIG. 6) multilayering one or more sheets of the first ceramic members 310 configuring the piezoelectric vibration device 30 and the second ceramic member 410 configuring the capacitor 40.

Here, the electrode pattern 50 may be provided on at least one surface of each of the first ceramic member 310 and the second ceramic member 410. For example, FIG. 6 shows that the electrode pattern 50 is formed only between the first ceramic member 310 and the second ceramic member 410, but the electrode pattern represented by reference numeral 52 may be formed on the top surface of the second ceramic member 410 in the present process.

Meanwhile, after the multilayering of the first ceramic member 310 and the second ceramic member 410 is completed, the compressing and sintering process integrating the first ceramic member 310 and the second ceramic member 410 may be further performed.

(Forming Electrode Pattern)

The forming may be performed to form the electrode patterns 52, 54, and 56 in the ceramic members 310 and 410. Describing in detail, the electrode patterns 52, 54, and 56 may be further formed on outer surfaces of the ceramic members 310 and 410.

For example, the electrode pattern represented by reference numerals 52 may be formed on the top surface of the second ceramic member 410, the electrode pattern represented by reference numeral 54 may be formed on the surfaces of the first ceramic member 310 and the second ceramic member 410, and the electrode pattern represented by reference numeral 56 may be formed on the second end surfaces of the first ceramic member 310 and the second ceramic member 410 and the bottom surface of the first ceramic member 310.

Here, the electrode pattern 54 may be used as an external electrode connected with the electrode pattern represented by reference numeral 50 and having the first polarity, and the electrode pattern 56 may be used as an external electrode having the second polarity.

Therefore, the top surface and the bottom surface of the first ceramic member 310 may have different polarities by the electrode patterns 50, 54, and 56.

However, the electrode patterns represented by reference numerals 52 and 56 are separated from each other and thus, the top surface and the bottom surface of the ceramic member 410 may not have different polarities.

(Polarizing)

The polarizing may be performed to polarize the first ceramic member 310.

The top surface and the bottom surface of the first ceramic member 310 may have different polarities by the electrode pattern 50 and the electrode pattern 56 as described above. Therefore, when the high voltage having a predetermined magnitude is generated in the electrode patterns 54 and 56, the polarization may be formed inside the first ceramic member 310.

Unlike this, the second ceramic member 410 does not form different polarities in the top surface and the bottom surface thereof even when high voltage having a predetermined magnitude is generated by the electrode patterns 54 and 56, and thus, the polarization may not be formed therein.

Therefore, when the present process is completed, the first ceramic member 310 may have a piezoelectric vibration element characteristic and the second ceramic member 410 may maintain a capacitor characteristic.

(Connecting Electrode Pattern)

The connecting may be performed to connect the electrode patterns 52 and 56.

In order for the second ceramic member 410 to be used as the capacitor 40, there is a need to connect the electrode pattern 52 with the electrode pattern represented by reference numeral 56.

Therefore, the electrode pattern 52 may be connected with the electrode pattern 56 by a conductive material. For reference, the conductive material may be a conductive adhesive including metal powder.

Meanwhile, this connecting may be performed after the following assembling.

That is, after the ceramic members 310 and 410 are mounted in the case 20 of the ultrasonic sensor 10 in a state in which a connection terminal is connected with the electrode patterns 54 and 56, the connecting of the electrode patterns 52 and 56 may be performed.

The method of manufacturing an ultrasonic sensor according to the embodiment of the present invention configured as described above is a method for multilayering the ceramic members 310 and 410 and then, partially polarizing the ceramic member. Therefore, there is no need to separate and prepare the ceramic member 310 for the piezoelectric vibration element 30 and the ceramic member 410 for the capacitor 40. Therefore, the embodiment of the present invention may be applied to mass production of ultrasonic sensors.

Meanwhile, although the accompanying specification and drawings describe that the ceramic members 310 and 410 configure a pair of piezoelectric vibration element 30 and capacitor 40, several pairs of piezoelectric vibration elements 30 and capacitors 40 may be simultaneously manufactured by cutting the ceramic members 310 and 410 in a predetermined size.

As set forth above, according to the embodiments of the present invention, the ultrasonic sensor may be miniaturized and the manufacturing process of the ultrasonic sensor may be simplified by integrally forming the piezoelectric element and the temperature compensation device.

While the present invention has been shown and described in connection with the embodiments, it will be apparent to those skilled in the art that modifications and variations can be made without departing from the spirit and scope of the invention as defined by the appended claims.

What is claimed is:

1. An ultrasonic sensor, comprising:
a piezoelectric vibration element; and
a capacitor integrally formed with the piezoelectric vibration element.

2. The ultrasonic sensor of claim 1, wherein the piezoelectric vibration element includes a polarized ceramic member.

3. The ultrasonic sensor of claim 1, wherein the capacitor includes a non-polarized ceramic member.

4. The ultrasonic sensor of claim 1, further comprising an electrode pattern connecting the piezoelectric vibration element to the capacitor.

5. The ultrasonic sensor of claim 1, wherein the piezoelectric vibration element and the capacitor are formed as a ceramic multilayered structure.

6. The ultrasonic sensor of claim 5, wherein the ceramic multilayered structure includes:
a first ceramic member having a first electrode pattern formed on a top surface thereof and configuring the piezoelectric vibration element; and
a second ceramic member formed on the first ceramic member, having a second electrode pattern, and configuring the capacitor.

7. The ultrasonic sensor of claim 6, further comprising:
a third electrode pattern formed on a first end surface of the first ceramic member and a first end surface of the second ceramic member and connected with the first electrode pattern; and
a fourth electrode pattern formed on a second end surface of the first ceramic member and a second end surface of the second ceramic member and connected with the second electrode pattern.

8. The ultrasonic sensor of claim 7, further comprising a case formed of a conductive material,
wherein the case is electrically connected with the fourth electrode pattern.

9. The ultrasonic sensor of claim 8, further comprising:
a first connection terminal electrically connected with the case; and
a second connection terminal electrically connected with the third electrode pattern.

10. The ultrasonic sensor of claim 6, further comprising:
a third electrode pattern formed on the first end surface of the first ceramic member and the first end surface of the second ceramic member and connected with the first electrode pattern; and
a fourth electrode pattern formed on the second end surface of the first ceramic member and the second end surface of the second ceramic member and connected with the second electrode pattern.

11. The ultrasonic sensor of claim 10, further comprising:
a first connection terminal electrically connected with the fourth electrode pattern; and
a second connection terminal electrically connected with the third electrode pattern.

12. The ultrasonic sensor of claim 5, wherein the ceramic multilayered structure includes:
at least two 1a ceramic members having a 1a electrode pattern extending from the top surface thereof to the first end surface thereof;
a 1b ceramic member having a 1b electrode pattern extending from the top surface thereof to the second end surface thereof, and disposed between the 1a ceramic members; and
a second ceramic member formed on the top surface of the 1a ceramic member and having the second electrode pattern formed on the top surface thereof,
the 1a and 1b ceramic members configuring the piezoelectric vibration element and the second ceramic member configuring the capacitor.

13. A method of manufacturing an ultrasonic sensor, comprising:
preparing a first polarized ceramic member;
forming a second non-polarized ceramic member on a top surface of the first polarized ceramic member; and
compressing and sintering the first polarized ceramic member and the second non-polarized ceramic member.

14. The method of claim 13, further comprising forming an electrode pattern in the first polarized ceramic member and the second non-polarized ceramic member.

15. The method of claim 13, wherein the preparing includes applying high voltage to the first polarized ceramic member.

16. A method of manufacturing an ultrasonic sensor, comprising:
preparing a first ceramic member having electrode patterns formed on a top surface and a bottom surface thereof;
preparing a second ceramic member having the electrode pattern formed on the top surface thereof;
multilayering the first ceramic member and the second ceramic member and compressing and sintering the multilayered first ceramic member and second ceramic member; and
polarizing the first ceramic member by applying high voltage to the electrode pattern of the first ceramic member.

17. The method of claim 16, further comprising connecting the electrode pattern of the first ceramic member and the electrode pattern of the second ceramic member to each other.
